(19) United States
(12) Patent Application Publication
(10) Pub. No.: US 2023/0120199 A1
(43) Pub. Date: Apr. 20, 2023

(54) COPPER INTERCONNECTS WITH AN EMBEDDED DIELECTRIC CAP BETWEEN LINES

(71) Applicant: International Business Machines Corporation, Armonk, NY (US)

(72) Inventors: Koichi Motoyama, Clifton Park, NY (US); CHANRO PARK, CLIFTON PARK, NY (US); Kenneth Chun Kuen Cheng, Shatin (HK); Chih-Chao Yang, Glenmont, NY (US)

(21) Appl. No.: 17/493,884

(22) Filed: Oct. 5, 2021

(51) Int. Cl. H01L 21/768; H01L 23/532; H01L 23/528; H01L 23/522

(52) U.S. Cl. CPC H01L 21/76829; H01L 21/76849; H01L 23/5226; H01L 23/5283; H01L 23/53233; H01L 21/76835; H01L 21/76879

(57) ABSTRACT

A copper interconnect with an embedded dielectric cap between lines comprises a plurality of interconnect lines formed in a dielectric layer of a semiconductor device. The copper interconnect further comprises a first dielectric cap formed between each interconnect line of the plurality of interconnect lines. The copper interconnect further comprises a second dielectric cap formed on top of the plurality of interconnect lines and the first dielectric cap, wherein the second dielectric cap formed on top of the first dielectric cap forms a bi-layer dielectric cap between the plurality of interconnect lines.

### BACKGROUND

The present invention relates generally to the fabrication of semiconductor devices, and more particularly to copper (Cu) interconnects with an embedded dielectric cap between lines.

In integrated circuits (ICs), interconnects are structures that connect two or more circuit elements (such as transistors) together electrically. The design and layout of interconnects on an IC is vital to its proper function, performance, power efficiency, reliability, and fabrication yield. The material that interconnects are made from depends on many factors. Chemical and mechanical compatibility with the semiconductor substrate and the dielectric in between the levels of interconnect is necessary, otherwise barrier layers are needed. Suitability for fabrication is also required; some chemistries and processes prevent integration of materials and unit processes into a larger technology (recipe) for IC fabrication. In fabrication, interconnects are formed during the Back End of Line (BEOL) after the fabrication of the transistors on the substrate.

Copper interconnects are used in silicon ICs to reduce propagation delays and power consumption. Since copper is a better conductor than aluminum, ICs using copper for their interconnects can have interconnects with narrower dimensions and use less energy to pass electricity through them. Together, these effects lead to ICs with better performance. The transition from aluminum to copper required significant developments in fabrication techniques, including radically different methods for patterning the metal as well as the introduction of barrier metal layers to isolate the silicon from potentially damaging copper atoms.

Time-Dependent Dielectric Breakdown (TDDB) is a kind of transistor aging, a failure mechanism in MOSFETs, when the gate oxide breaks down as a result of long-time application of relatively low electric field (as opposed to immediate breakdown, which is caused by strong electric field). The breakdown is caused by formation of a conducting path through the gate oxide to substrate due to electron tunneling current, when MOSFETs are operated close to or beyond their specified operating voltages.

### SUMMARY

Embodiments of the present invention include copper interconnects with an embedded dielectric cap between lines and a method of making the same. The interconnect structure comprises a plurality of interconnect lines formed in a dielectric layer of a semiconductor device. The copper interconnect further comprises a first dielectric cap formed between each interconnect line of the plurality of interconnect lines. The copper interconnect further comprises a second dielectric cap formed on top of the plurality of interconnect lines and the first dielectric cap, wherein the second dielectric cap formed on top of the first dielectric cap forms a bi-layer dielectric cap between the plurality of interconnect lines.

The method of making the copper interconnects with an embedded dielectric cap between lines includes forming a plurality of cut cavities in a layer of a dielectric material on an interconnect structure, wherein each cut cavity of the plurality of cut cavities forms a line cut. Next, a barrier material is deposited over a first exposed surfaces of each cut cavity of the plurality of cut cavities to form a barrier in each cut cavity. Next, a liner material is deposited over a second exposed surfaces of the barrier material. Next, the plurality of cut cavities is filled with a first metal. Next, the first top surface of the base dielectric and the plurality of cut cavities is planarized to form one or more lines. Next, a second metal is selectively deposited to form a cap over a third exposed surfaces of the one or more lines. Next, a portion of the base dielectric is selectively removed to create a recess between each line of the one or more lines, where the recess extends below a top surface of the liner material. Next, a first dielectric cap is deposited on the first exposed surfaces of each line of the one or more lines and a fourth exposed surfaces of the base dielectric. Next, the first dielectric cap is planarized, where the first dielectric cap is planarized to a second top surface of the second metal. Finally, a second dielectric cap is deposited on a fifth exposed surfaces of each line of the one or more lines and a sixth exposed surfaces of the first dielectric cap.

### BRIEF DESCRIPTION OF THE DRAWINGS

FIG. 1 depicts a cross-sectional view of an interconnect structure including the interface between a metal cap and a dielectric material in a semiconductor device.

FIG. 2 depicts a cross-sectional view of an interconnect structure illustrating a misalignment between a line and a via in a semiconductor device.

FIG. 3 depicts a cross-sectional view of an interconnect structure with an embedded dielectric cap between lines in a semiconductor device, in accordance with an embodiment of the present invention.

FIG. 4 depicts a cross-sectional view of an interconnect structure after fabrication steps depositing copper, a liner, and a barrier, and chemical mechanical polishing (CMP) on a layer of a semiconductor, in accordance with an embodiment of the present invention.

FIG. 5 depicts a cross-sectional view of the interconnect structure after fabrication steps to selectively deposit metal caps on the exposed surface of the interconnect structure of FIG. 4, in accordance with an embodiment of the present invention.

FIG. 6 depicts a cross-sectional view of the interconnect structure after fabrication steps to create recesses on the exposed surfaces of the dielectric layer of the interconnect structure of FIG. 5, in accordance with an embodiment of the present invention.

FIG. 7 depicts a cross-sectional view of the interconnect structure after fabrication steps to deposit a first dielectric cap on the exposed surface of the interconnect structure of FIG. 6, in accordance with an embodiment of the invention.

FIG. 8 depicts a cross-sectional view of the interconnect structure after fabrication steps to planarize the dielectric cap of the interconnect structure of FIG. 7, in accordance with an embodiment of the invention.

FIG. 9 depicts a cross-sectional view of the interconnect structure after fabrication steps to deposit a second dielectric cap on the exposed surface of the interconnect structure of FIG. 8, in accordance with an embodiment of the invention.

FIG. 10 depicts a cross-sectional view of the interconnect structure after steps to fabricate a via layer on the top surface of the interconnect structure of FIG. 9, and an additional metal layer on the top surface of the via layer, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps depicted can be combined as an integrated process step. In addition, descriptions of well-known functions and constructions may be omitted for clarity and conciseness.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For BEOL copper interconnects with a pitch below 30 nm, line to line TDDB is one of the biggest concerns due to the very small space between the lines. The interface between the cap dielectric material and the low-k dielectric material is the main Cu diffusion path to cause TDDB performance degradation. Selectivity of the metal cap process at small pitch is another TDDB related concern. Furthermore, in case of having misalignment between a line and a via above the line, there will likely be a micro-trenching issue which causes voltage breakdown (Vbd) degradation. Therefore, the interface between the cap and the low-k dielectric needs to be addressed.

Embodiments of the present invention generally provide a new process of forming an interconnect structure with an embedded bi-layer dielectric cap between the lines. Embodiments of the present invention utilize copper interconnects. The use of embedded caps between the lines by the present invention improves TDDB performance. In addition, the present invention prevents micro-trenching issues even in the case of misalignment between a line and a via above the line, which exhibits improved Vbd performance due to the increased space between a via and an adjacent line. The process also prevents metal residues between the interconnect lines.

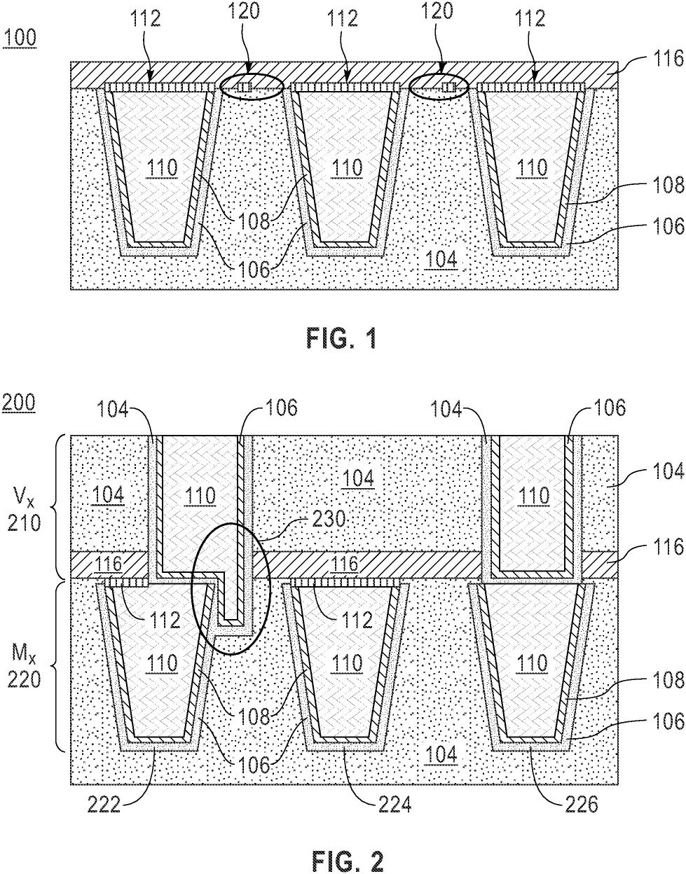

FIG. 1 depicts a cross-sectional view of an interconnect structure including the interface between a metal cap and a dielectric material in a semiconductor device. Interconnect structure 100 includes dielectric 104, typically a low-k dielectric constant material; barrier 106, which may be, for example, Tantalum nitride (TaN); and liner 108, which may be, for example, Ruthenium (Ru), around copper interconnect 110. Interconnect structure 100 also includes metal cap 112, which may be, for example, cobalt (Co), and cap dielectric 116, which may be, for example, silicon carbonitride (SiCN). This method of fabrication, however, leads to several issues. The interface between metal cap 112 and dielectric 104 is the main copper diffusion path. As can be seen in notes 120, metal residue may be present between the lines that can cause TDDB degradation. Another potential issue is illustrated in FIG. 2 below.

FIG. 2 depicts a cross-sectional view of interconnect structure 200 illustrating a misalignment between a line and a via in a semiconductor device. The example illustrated in FIG. 2 includes via 212 and via 214 on via layer V_{X} 210, and line 222, line 224, and line 226 on metal layer M_{X}220. In this example, via 212 is misaligned on top of line 222. Misalignment between line 222 and via 212 causes micro-trenching, as can clearly be seen in note 230, which leads to Vbd degradation.

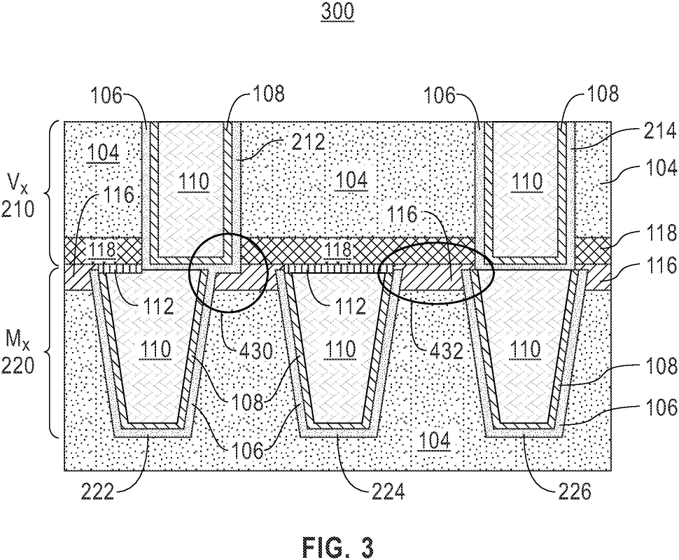

FIG. 3 depicts a cross-sectional view of interconnect structure 300 with an embedded dielectric cap between lines in a semiconductor device, in accordance with an embodiment of the present invention. In the cross-sectional view of interconnect structure 300, a conventional blanket dielectric cap 118 has been added on the top surface of lines 222-226 and the top surface of cap dielectric 116. This results in a bi-layer dielectric cap formed by the combination of blanket dielectric cap 118 and cap dielectric 116.

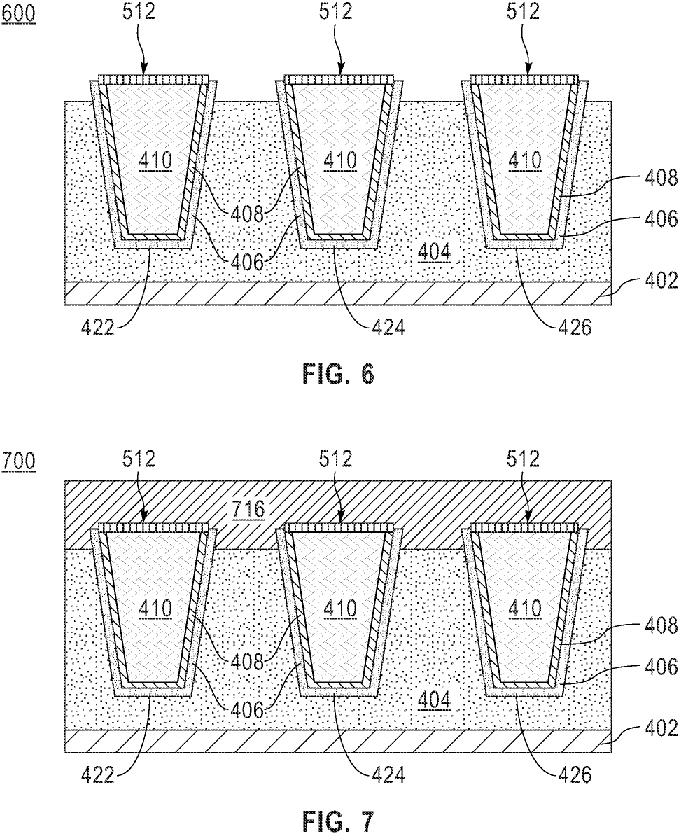

In contrast to the example of FIG. 2, although via 212 is misaligned above line 222, the embedded dielectric cap between line 222 and line 224 of interconnect structure 300 prevents micro-trenching of via 212 below the dielectric surface, as can be seen by detail 430. In addition, as is highlighted by detail 432, the fabrication step to create recesses in dielectric 104 (see FIG. 6 below) removes metal residues between the lines, so no metal residues exist between lines.

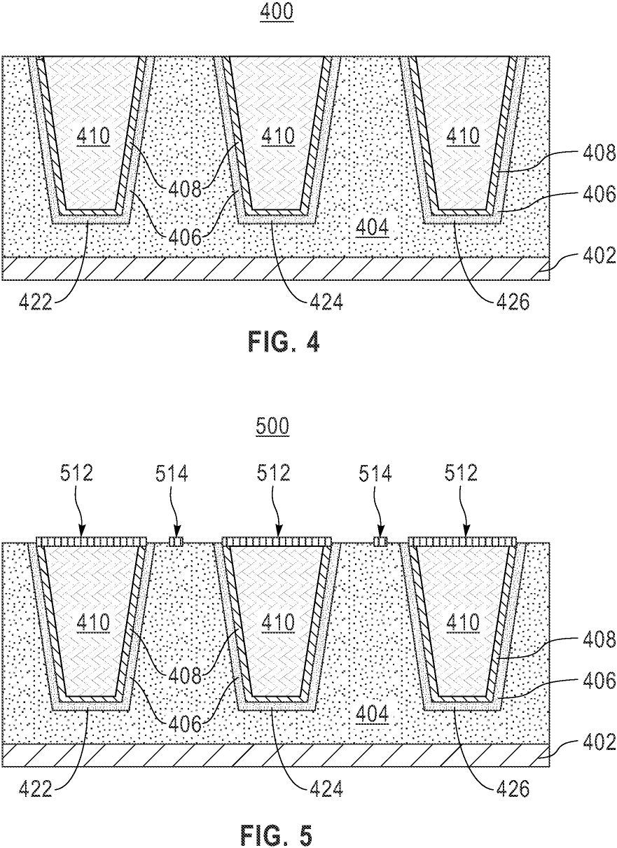

FIG. 4 depicts a cross-sectional view of interconnect structure 400 after fabrication steps depositing copper, a liner, and a barrier, and planarization on a layer of a semiconductor, in accordance with an embodiment of the present invention. Since the present invention is directed to BEOL semiconductor fabrication, substrate layer 402 is illustrated as a generic layer. However, in various embodiments, substrate layer 402 may be a semiconductor wafer or may be a layer containing circuitry manufactured during front end of line (FEOL) processes such as, for example, transistors, capacitors, resistors, etc.

In the cross-sectional view of FIG. 4, dielectric 404 has been deposited on substrate layer 402. In an embodiment, dielectric 404 is dielectric 104 from FIGS. 1-3. In an embodiment, dielectric 404 is a low-k dielectric, e.g., SiCOH. In an embodiment, dielectric 404 is deposited or formed on exposed surfaces of substrate layer 402 using conventional processes. In the cross-sectional view of FIG. 4, after dielectric 404 is deposited on substrate layer 402, cut cavities are etched into dielectric 404, and barrier 406, liner 408, and copper interconnect 410, e.g., barrier 106, liner 108, and copper interconnect 110, respectively, from FIGS. 1-3, are deposited to form line 422, line 424, and line 426. In an embodiment, barrier 406 may be, for example, TaN. In an embodiment, liner 408 may be, for example, Ru.

In an embodiment, after the deposition of copper interconnect 410, the surface of the device is planarized using, for example, CMP.

FIG. 5 depicts a cross-sectional view of interconnect structure 500 after fabrication steps to selectively deposit metal caps on the exposed surface of the interconnect structure of FIG. 6, in accordance with an embodiment of the present invention. In the embodiment illustrated in FIG. 5, metal caps 512 have been selectively deposited on the top surface on the top surface of lines 422-426. In an embodiment, selectivity issues may lead to metal residues 514 between the lines on the surface of dielectric 404 after the selective deposition of metal caps 512.

In an embodiment, metal cap 512 is cobalt. In another embodiment, selectively deposited may be any appropriate metal that can be selectively deposited as would be known to a person of skill in the art. In an embodiment, metal cap 512 is deposited using chemical vapor deposition (CVD).

FIG. 6 depicts a cross-sectional view of interconnect structure 600 after fabrication steps to create recesses on the exposed surfaces of the dielectric layer of the interconnect structure of FIG. 5, in accordance with an embodiment of the present invention. In an embodiment, a diluted hydrofluoric acid (dHF) dip cleaning process may be used to under-etch a recess in dielectric 404. In another embodiment, any other appropriate etching process may be used to etch a recess in dielectric 404 as would be known to a person of skill in the art. As a result of creating the recesses, any metal residues between the metal lines is completely removed by this step.

FIG. 7 depicts a cross-sectional view of interconnect structure 700 after fabrication steps to deposit a first dielectric cap on the exposed surface of the interconnect structure of FIG. 6, in accordance with an embodiment of the invention. In the cross-sectional view of FIG. 7, first dielectric cap 716 has been deposited on the exposed top surface of interconnect structure 700, covering lines 422-426 and dielectric 404.

In an embodiment, first dielectric cap 716 is a dielectric material which has a high Vbd. In an embodiment, first dielectric cap 716 is SiCN. In another embodiment, first dielectric cap 716 may be any other appropriate dielectric material as would be known to a person of skill in the art.

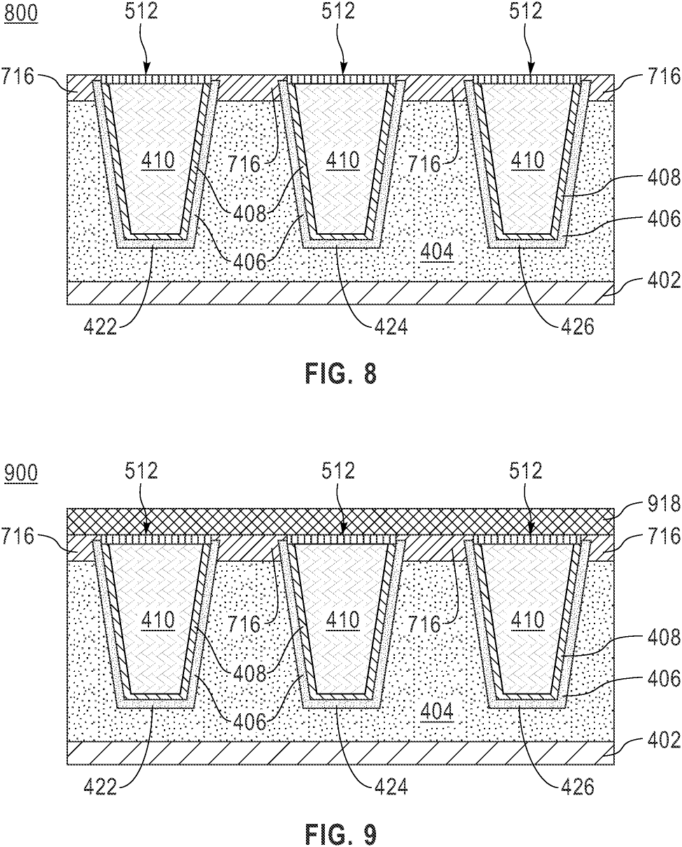

FIG. 8 depicts a cross-sectional view of interconnect structure 800 after fabrication steps to planarize the dielectric cap of the interconnect structure of FIG. 7, in accordance with an embodiment of the invention. In an embodiment, after the deposition of first dielectric cap 716, the surface of the device is planarized using, for example, CMP. In an embodiment, the surface of interconnect structure 800 is planarized to the top surface of metal lines 422-426.

FIG. 9 depicts a cross-sectional view of interconnect structure 900 after fabrication steps to deposit a second dielectric cap on the exposed surface of the interconnect structure of FIG. 8, in accordance with an embodiment of the invention. In the cross-sectional view of FIG. 9, second dielectric cap 918 has been deposited on the exposed top surface of first dielectric cap 716 as well as the exposed top surfaces of lines 422-426.

In an embodiment, second dielectric cap 918 is a dielectric material which has a high etch stop capability. In an embodiment, second dielectric cap 918 is aluminum oxide (AlOx). In another embodiment, second dielectric cap 918 may be any other appropriate dielectric material as would be known to a person of skill in the art.

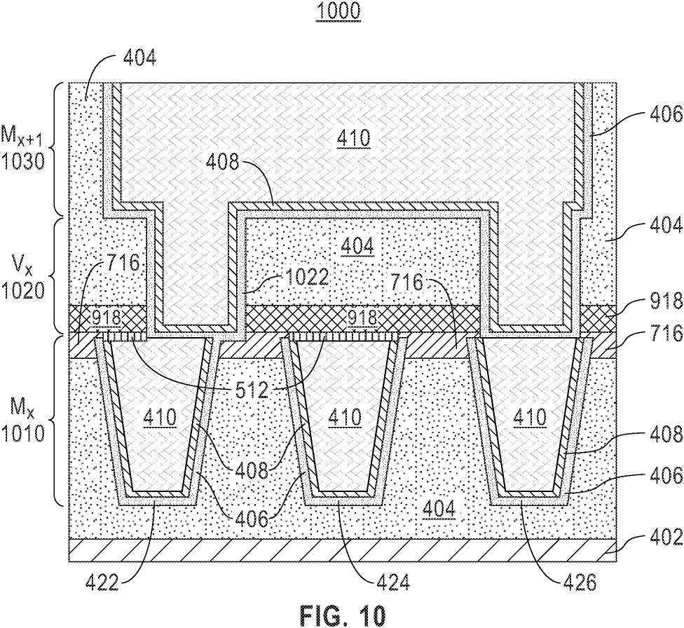

FIG. 10 depicts a cross-sectional view of interconnect structure 1000 after steps to fabricate a via layer on the top surface of the interconnect structure of FIG. 9, and an additional metal layer on the top surface of the via layer, in accordance with an embodiment of the invention. The cross-sectional view of interconnect structure 1000 illustrates three layers of the semiconductor structure, metal layer M_{X} 1010, via layer V_{X} 1020, and next metal layer M_{X}+₁ 1030. In the cross-sectional view of interconnect structure 1000 illustrated in FIG. 10, via 1022 has been fabricated on the top surface of line 422, but via 1022 is misaligned above line 422. Unlike the example shown in FIG. 2 above, however, in this example the use of the embedded dielectric cap between line 422 and line 424 has prevented micro-trenching of via 1022 below the dielectric surface.

What is claimed is:

1. An interconnect structure comprising:
a plurality of interconnect lines formed in a dielectric layer of a semiconductor device;
a first dielectric cap formed between each interconnect line of the plurality of interconnect lines; and
a second dielectric cap formed on top of the plurality of interconnect lines and the first dielectric cap, wherein the second dielectric cap formed on top of the first dielectric cap forms a bi-layer dielectric cap between the plurality of interconnect lines.

2. The interconnect structure of claim 1, wherein the plurality of interconnect lines are formed of copper (Cu).

3. The interconnect structure of claim 1, wherein the first dielectric cap has a high voltage breakdown (Vbd).

4. The interconnect structure of claim 3, wherein the first dielectric cap material is silicon carbonitride (SiCN).

5. The interconnect structure of claim 1, wherein the second dielectric cap has a high etch stop capability.

6. The interconnect structure of claim 5, wherein the second dielectric cap material is aluminum oxide (AlOx).

7. The interconnect structure of claim 1, wherein the dielectric layer is a low-k dielectric constant material.

8. The interconnect structure of claim 1, wherein the plurality of interconnect lines formed in the dielectric layer of the semiconductor device comprises:
a cut etched in the dielectric layer for each interconnect line of the plurality of interconnect lines;
a barrier material deposited on a first exposed surfaces of the cut etched in the dielectric layer for each interconnect line;
a liner material deposited on a second exposed surfaces of the barrier; and
the cut filled by depositing copper to fill the cut etched in the dielectric layer for each interconnect line of the plurality of interconnect lines.

9. The interconnect structure of claim 8, wherein the barrier material is Tantalum nitride (TaN).

10. The interconnect structure of claim 8, wherein the liner material is Ruthenium (Ru).

11. The interconnect structure of claim 1, wherein the bi-layer dielectric cap between the plurality of interconnect lines prevents micro-trenching in case of a misalignment between a via and a line.

12. The interconnect structure of claim 11, wherein preventing micro-trenching exhibits improved Vbd performance due to increased space between the via and an adjacent line.

13. The interconnect structure of claim 1, wherein the bi-layer dielectric cap between the plurality of interconnect lines exhibits better Time-Dependent Dielectric Breakdown (TDDB) performance.

14. The interconnect structure of claim 1, wherein the second dielectric cap forms a conventional blanket dielectric cap on a top surface of the plurality of interconnect lines.

15. A method of forming an interconnect structure, the method comprising:
forming a plurality of cut cavities in a layer of a base dielectric material on an interconnect structure, wherein each cut cavity of the plurality of cut cavities forms a line cut;
depositing a barrier material over a first exposed surfaces of each cut cavity of the plurality of cut cavities to form a barrier in each cut cavity;
depositing a liner material over a second exposed surfaces of the barrier material;
filling the plurality of cut cavities with a first metal;
planarizing a first top surface of the base dielectric and the plurality of cut cavities to form one or more lines;
selectively depositing a second metal to form a cap over a third exposed surfaces of the one or more lines;
selectively removing a portion of the base dielectric to create a recess between each line of the one or more lines, wherein the recess extends below a top surface of the liner material;
depositing a first dielectric cap on the first exposed surfaces of each line of the one or more lines and a fourth exposed surfaces of the base dielectric;
planarizing the first dielectric cap, wherein the first dielectric cap is planarized to a second top surface of the second metal; and
depositing a second dielectric cap on a fifth exposed surfaces of each line of the one or more lines and a sixth exposed surfaces of the first dielectric cap.

16. The method of claim 15, wherein planarizing the first top surface of the base dielectric and the plurality of cut cavities to form the one or more lines comprises:
using chemical mechanical polishing to planarize the top surface to form the one or more lines.

17. The method of claim 15, wherein selectively depositing the second metal to form the cap over the third exposed surfaces of the one or more lines comprises:
using chemical vapor deposition to selectively deposit the second metal.

18. The method of claim 15, wherein selectively removing the portion of the base dielectric to create the recess between each line of the one or more lines, wherein the recess extends below the top surface of the liner material further comprises:
removing one or more metal residues between the one or more lines.

19. The method of claim 15, wherein selectively removing the portion of the base dielectric to create the recess between each line of the one or more lines, wherein the recess extends below the top surface of the liner material comprises:
using a diluted hydrofluoric acid (dHF) dip cleaning process to under-etch the recess between each line of the one or more lines.

20. The method of claim 15, wherein planarizing the first dielectric cap, wherein the first dielectric cap is planarized to the second top surface of the second metal comprises:
using chemical mechanical polishing to planarize the first dielectric cap.
